(19) United States
(12) Patent Application Publication
(10) Pub. No.: US 2013/0032913 A1
(43) Pub. Date: Feb. 7, 2013

(54) GRAPHENE STRUCTURE, PRODUCTION METHOD THEREOF, PHOTOELECTRIC CONVERSION ELEMENT, SOLAR CELL, AND IMAGE PICKUP APPARATUS

(71) Applicants: Nozomi Kimura, Kanagawa (JP); Daisuke Hobara, Kanagawa (JP); Toshiyuki Kobayashi, Kanagawa (JP); Masashi Bando, Kanagawa (JP); Keisuke Shimizu, Kanagawa (JP); Koji Kadono, Tokyo (JP)

(72) Inventors: Nozomi Kimura, Kanagawa (JP); Daisuke Hobara, Kanagawa (JP); Toshiyuki Kobayashi, Kanagawa (JP); Masashi Bando, Kanagawa (JP); Keisuke Shimizu, Kanagawa (JP); Koji Kadono, Tokyo (JP)

(73) Assignee: SONY CORPORATION, Tokyo (JP)

(21) Appl. No.: 13/558,062

(22) Filed: Jul. 25, 2012

(30) Foreign Application Priority Data
Aug. 4, 2011 (JP) 2011-170810

(51) Int. Cl. H01L 31/0224; B32B 9/00; B32B 37/14; B82Y 30/00

(52) U.S. Cl. 257/431; 156/60; 428/408; 257/E31.126; 977/734

(57) ABSTRACT

A graphene structure includes a conductive layer and a protective layer. The conductive layer is formed of graphene doped with a dopant, and the protective layer is laminated on the conductive layer and formed of a material having a higher oxidation-reduction potential than water.

### CROSS REFERENCES TO RELATED APPLICATIONS

The present application claims priority to Japanese Priority Patent Application JP 2011-170810 filed in the Japan Patent Office on Aug. 4, 2011, the entire content of which is hereby incorporated by reference.

### BACKGROUND

The present disclosure relates to a graphene structure including doped graphene, a production method thereof, and a photoelectric conversion element, a solar cell, and an image pickup apparatus that use the graphene structure.

Graphene is a sheet-like material made of carbon atoms arranged in a hexagonal grid structure and is attracting attention as an electrode material or the like of a touch panel, a solar cell, or the like, because of its conductivity and optical transparency. Here, in recent years, it has been found that it is possible to increase a carrier concentration of graphene and reduce electrical resistance (increase conductivity) of graphene by doping the graphene with a dopant.

However, there is a problem that the carrier concentration of graphene is gradually reduced (resistance gradually increases) with an elapse of time in a case where the carrier concentration of graphene is equal to or larger than a certain value due to doping, although the conduction characteristic of undoped graphene is stable regardless of time. For example, since the conduction characteristic of a device using graphene changes with an elapse of time, it causes a problem in terms of accuracy or the like.

To solve such a problem, for example, “Layer-by-Layer Doping of Few-Layer Graphene Film” by Fethullah Gunes et al., ACS Nano, Jul. 27, 2010, Vol. 4, No. 8, pp 4595-4600 (hereinafter referred to as Non-Patent Document 1) discloses a technique of suppressing a time degradation of a conduction characteristic by inserting a dopant between layers of multilayer graphene (graphene laminated with a plurality of layers of single-layer graphene).

### SUMMARY

However, in the technique described in Non-Patent Document 1, there has been a problem that the suppressive effect of the time degradation of the conduction characteristic is small and the optical transparency is lower than that in a case where single-layer graphene is used because the technique uses multilayer graphene.

In view of the circumstances as described above, there is a need for a graphene structure that is capable of suppressing a time degradation of doped graphene, a production method thereof, and a photoelectric conversion element, a solar cell, and an image pickup apparatus that use the graphene structure.

According to an embodiment of the present disclosure, there is provided a graphene structure including a conductive layer and a protective layer.

The conductive layer is formed of graphene doped with a dopant.

The protective layer is laminated on the conductive layer and formed of a material having a higher oxidation-reduction potential than water.

According to this configuration, the protective layer having a higher oxidation-reduction potential than water can prevent water in an environment (in air or solution) from donating an electron to the conductive layer and prevent the time degradation of the conduction characteristic of the graphene.

The protective layer may be a sacrificial layer formed of a material which is reactive with water.

According to this configuration, the sacrificial layer can prevent water from donating an electron to the conductive layer by resolving water which has come into contact with the graphene structure.

The protective layer may be a nonaqueous solution layer formed of a nonaqueous solution.

According to this configuration, the nonaqueous solution layer formed of the nonaqueous solution (hydrophobic solution) can prevent water from donating an electron to the conductive layer by preventing water from coming into contact with the conductive layer.

The protective layer may be a sealing layer that is formed of a material that shields water and covers the conductive layer.

According to this configuration, the sealing layer can prevent water from donating an electron to the conductive layer by preventing water from coming into contact with the conductive layer.

The protective layer may be a surplus dopant layer formed of a surplus amount of the dopant which does not contribute to the doping.

According to this configuration, the surplus dopant layer formed of a surplus amount of the dopant which does not contribute to the doping can prevent water from donating an electron to the conductive layer.

The protective layer may be a dried gas layer formed of a dried gas which does not contain water.

According to this configuration, the dried gas layer can prevent water from donating an electron to the conductive layer by preventing water from coming into contact with the conductive layer.

According to an embodiment of the present disclosure, there is provided a method of producing a graphene structure, including

forming a conductive layer by doping graphene with a dopant, and

laminating a protective layer formed of a material having a higher oxidation-reduction potential than water on the conductive layer.

According to an embodiment of the present disclosure, there is provided a photoelectric conversion element that uses a graphene structure as a transparent conductive film, the graphene structure including a conductive layer formed of graphene doped with a dopant and a protective layer that is laminated on the conductive layer and formed of a material having a higher oxidation-reduction potential than water.

According to this configuration, a photoelectric conversion element having a high photoelectric conversion efficiency and high temporal stability can be provided.

According to an embodiment of the present disclosure, there is provided a solar cell that uses a graphene structure as a transparent conductive film, the graphene structure including a conductive layer formed of graphene doped with a dopant and a protective layer that is laminated on the conductive layer and formed of a material having a higher oxidation-reduction potential than water.

According to this configuration, a solar cell having a high power generating efficiency and high temporal stability can be provided.

According to an embodiment of the present disclosure, there is provided an image pickup apparatus that uses a graphene structure as a transparent conductive film, the graphene structure including a conductive layer formed of graphene doped with a dopant and a protective layer that is laminated on the conductive layer and formed of a material having a higher oxidation-reduction potential than water.

According to this configuration, an image pickup apparatus having high temporal stability can be provided.

As described above, according to the embodiments of the present disclosure, it is possible to provide a graphene structure that is capable of suppressing a time degradation of doped graphene, a production method thereof, and a photoelectric conversion element, a solar cell, and an image pickup apparatus that use the graphene structure.

These and other objects, features and advantages of the present disclosure will become more apparent in light of the following detailed description of best mode embodiments thereof, as illustrated in the accompanying drawings.

Additional features and advantages are described herein, and will be apparent from the following Detailed Description and the figures.

### BRIEF DESCRIPTION OF THE FIGURES

FIG. 1 is a schematic diagram showing a graphene structure according to a first embodiment of the present disclosure;

FIG. 2 is another schematic diagram showing the graphene structure according to the first embodiment of the present disclosure;

FIGS. 3A to 3C is a band diagram showing a graphene structure according to a comparison;

FIGS. 4A to 4C is a schematic diagram showing a production method of the graphene structure according to the first embodiment of the present disclosure;

FIG. 5 is a schematic diagram showing a graphene structure according to a second embodiment of the present disclosure;

FIG. 6 is a schematic diagram showing a graphene structure according to a third embodiment of the present disclosure;

FIG. 7 is a schematic diagram showing a graphene structure according to a fourth embodiment of the present disclosure; and

FIG. 8 is a schematic diagram showing a graphene structure according to a fifth embodiment of the present disclosure.

### DETAILED DESCRIPTION

Hereinafter, embodiments of the present disclosure will be described with reference to the drawings.

### First Embodiment

A graphene structure according to a first embodiment of the present disclosure will be described.

(Configuration of Graphene Structure)

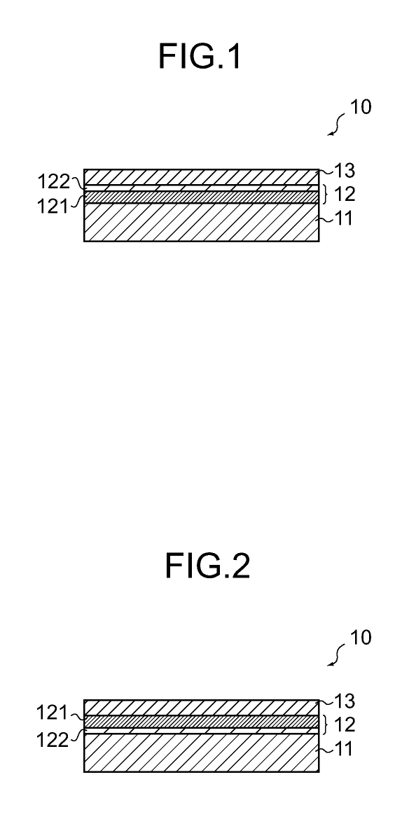

FIGS. 1 and 2 are schematic diagrams showing a layer construction of a graphene structure 10 according to this embodiment. As shown in these figures, the graphene structure 10 is formed by laminating a substrate 11, a conductive layer 12, and a sacrificial layer 13 in the stated order.

The substrate 11 is a supporting substrate of the graphene structure 10. The material of the substrate 11 is not particularly limited and may be a quartz substrate, for example. If the graphene structure 10 is expected to have optical transparency, the substrate 11 may be formed of a material having optical transparency.

The conductive layer 12 is constituted of a graphene layer 121 and a dopant layer 122. With respect to the graphene layer 121 and the dopant layer 122, the graphene layer 121 may be a lower layer (on the side of the substrate 11) as shown in FIG. 1, or the dopant layer 122 may be a lower layer as shown in FIG. 2.

The graphene layer 121 is formed of graphene. Graphene is a sheet-like material made of sp²-bonded carbon atoms arranged in a planar hexagonal grid structure. The graphene may be unlaminated single-layer graphene or multilayer graphene laminated with a plurality of layers of single-layer graphene. In this embodiment, although the graphene is not limited to the above, the single-layer graphene is favorable in terms of the optical transparency of the graphene structure 10 and because no delamination is caused.

The dopant layer 122 is formed of a dopant. The dopant may be selected from a group consisting of, for example, nitric acid, TFSA (trifluoromethanesulfonate), gold chloride, palladium chloride, ferric chloride, silver chloride, platinum chloride, and gold iodide, each of which being a material having a higher oxidation-reduction potential than water. As shown in FIG. 1 or FIG. 2, since the dopant layer 122 is in contact with the graphene layer 121, the dopant located near the interface is chemically adsorbed by the graphene of the graphene layer 121 to be doped (chemical doping).

The sacrificial layer 13 is formed of a material that has a higher oxidation-reduction potential than water and reacts with water. Water in an environment (in air or solution) does not reach the conductive layer 12 because it reacts with the sacrificial layer 13 before reaching the conductive layer 12. This prevents the time degradation of the conduction characteristic of the conductive layer 12. The reason for this will be described later.

The sacrificial layer 13 may further have a conductivity and optical transparency. The sacrificial layer 13 which has a conductivity can secure an electrical contact of the upper layer of the graphene structure 10 (on the opposite side of the substrate 11) to the conductive layer 12. Moreover, the sacrificial layer 13 which has optical transparency enables the graphene structure 10 to have optical transparency.

The sacrificial layer 13 does not need to cover the entire surface of the conductive layer 12 and may have, for example, a minute through-hole, because it only needs to be able to prevent water from reaching the conductive layer 12. In addition, even if the sacrificial layer 13 is formed of an insulating material, by making it thin, a current that flows through the conductive layer 12 can pass (leak) through the sacrificial layer 13 so that the electrical contact of the conductive layer 12 can be secured.

The graphene structure 10 according to this embodiment is formed as described above. The graphene structure 10 can be used as an electrode of a touch panel, a solar cell, or the like.

(Regarding Time Degradation of Conduction Characteristic)

The prevention of the time degradation of the conduction characteristic of the graphene structure 10 will be described. By way of comparison, a graphene structure which has no configuration corresponding to the sacrificial layer 13 (hereinafter referred to as “graphene structure according to a comparison”) will be described.

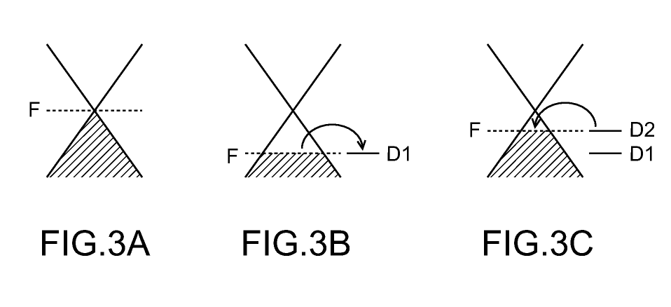

FIGS. 3a to 3c are band diagrams of the graphene structure according to the comparison. In these figures, an ordinate axis represents an energy level and dashed line F represents the Fermi level(an energy level with 50% chance of being occupied by an electron) of graphene. Electrons are filled below the Fermi level, and the abundance of electrons near the Fermi level corresponds to a carrier concentration.

FIG. 3A shows a state of (undoped) graphene in a vacuum environment. In a case where the graphene in this state is chemically doped with a dopant, the graphene donates an electron to the dopant until the Fermi level F of the graphene coincides with the oxidation-reduction potential D1 of the dopant, as shown in FIG. 3B.

Although it is ideal to maintain this state, that is not what happens actually. As shown in FIG. 3C, water in an environment acts as an electron donor, and the Fermi level of graphene increases up to the oxidation-reduction potential D2 of the water and the dopant with an elapse of time. As a result, the carrier concentration of graphene is decreased, and the conductivity of graphene is reduced. The inventors of the present disclosure experimentally found that water in an environment acts as an electron donor, in other words, the time degradation of the conduction characteristic of doped graphene is caused by water in an environment.

As described above, since the time degradation of the conduction characteristic is caused by water in an environment, it becomes possible to suppress the time degradation of the conduction characteristic, if water (including water in the liquid and gas phases) is prevented from donating an electron to graphene. In the graphene structure 10 according to this embodiment, since water in an environment reacts with the sacrificial layer 13 so as to prevent water from donating an electron to the conductive layer 12, it becomes possible to prevent the time degradation of the conduction characteristic of the conductive layer 12.

(Production Method of Graphene Structure)

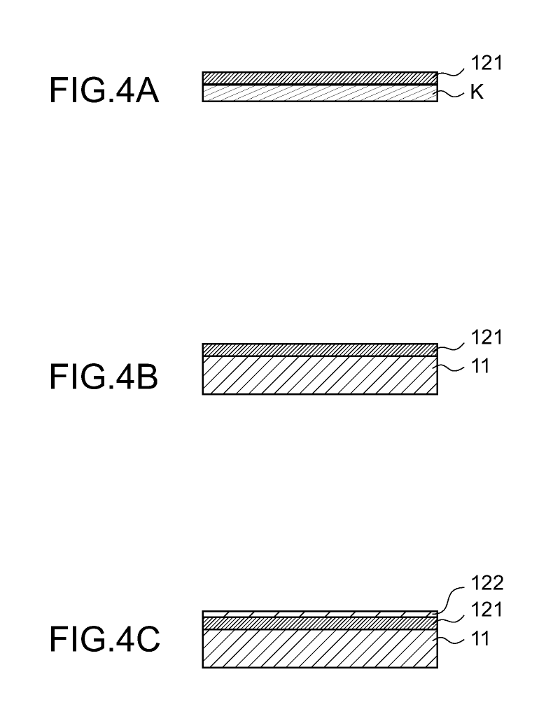

A production method of the graphene structure 10 will be described. FIG. 4 is a schematic diagram showing the production method of the graphene structure 10 shown in FIG. 1.

As shown in FIG. 4A, a film of graphene is formed on a catalyst substrate K to provide a graphene layer 121. This film formation is performed by using a thermal CVD (Chemical Vapor Deposition) method, a plasma CVD method, or the like. In the thermal CVD method, a carbon source material (material including a carbon atom) supplied to the surface of the catalyst substrate K is heated to form graphene. In the plasma CVD method, a carbon source material is turned into plasma to form graphene.

The material of the catalyst substrate K is not particularly limited, and nickel, iron, copper, or the like may be used as the material. It is favorable to use copper as the material of the catalyst substrate K, because this forms single-layer graphene having high adhesion. It is possible to form a film of graphene on the surface of the catalyst substrate K by supplying a carbon source material (e.g., methane) on the surface of the catalyst substrate K and heating the catalyst substrate K to a temperature equal to or higher than a graphene formation temperature. Specifically, it is possible to cause the graphene to grow by heating the catalyst substrate K to 960° C. and maintaining it for 10 minutes in a mixed gas atmosphere containing methane and hydrogen (for the reduction of the catalyst substrate K, methane:hydrogen=100 cc:5 cc).

Next, as shown in FIG. 4B, the graphene layer 121 is transferred onto an arbitrary substrate 11. Although the transferring method is not particularly limited, the method may be as follows. That is, a 4% PMMA (Poly(methyl methacrylate)) solution is applied onto the graphene layer 121 by spin-coating (2000 rpm, 40 seconds) and is baked at 130° C. for 5 minutes. Accordingly, a resin layer including PMMA is formed on the graphene layer 121. Next, the catalyst substrate K is etched (removed) by using a 1M ferric chloride solution.

After the graphene layer 121 on the resin layer is washed with ultrapure water, the graphene layer 121 is transferred to the substrate 11 (e.g., a quartz substrate) to be dried naturally. After drying, PMMA on the graphene layer 121 is dissolved by acetone to be removed. It is possible to remove the acetone by drying it in a vacuum under the heat of about 100° C. It should be noted that the PMMA may be removed by heating (annealing) and decomposing it in a hydrogen atmosphere at about 400° C. Accordingly, the graphene layer 121 is transferred onto the substrate 11. Other transferring methods include a method that uses an adhesive and a method that uses a thermal release tape, for example.

Next, as shown in FIG. 4C, the dopant layer 122 is laminated on the graphene layer 121, and graphene is doped with the dopant. This can be achieved by the method as follows, for example. Specifically, gold chloride is dried in a vacuum at room temperature for 4 hours. By dissolving it into a solvent (e.g., dehydrated nitromethane), a 10 mM solution (hereinafter referred to as dopant solution) is obtained. The dopant solution is applied onto the graphene layer 121 by bar-coating or spin-coating (2000 rpm, 40 seconds) in dry air and dried in a vacuum. Accordingly, the dopant layer 122 is formed.

It should be noted that it is desirable that the coating of the dopant solution is performed right after the annealing described above. This aims at preventing water in air from attaching to the graphene layer 121. Moreover, the solvent of the dopant solution described above is favorably a solvent that hardly absorbs water or a non-aqueous solvent. Furthermore, although the concentration of the dopant in the dopant solution can be selected as appropriate, the light transmission of the conductive layer 12 is reduced when the concentration is too high, and the degradation of the resistance is likely to be caused after the doping when the concentration is too low.

Next, the sacrificial layer 13 is laminated on the dopant layer 122 (see FIG. 1). A solution including the material of the sacrificial layer 13 is applied onto the dopant layer 122 by spin-coating and dried, for example. Accordingly, the sacrificial layer 13 can be formed. It is desirable that the spin coating is performed in dry air to prevent water in air from attaching to the dopant layer 122 or the like.

The graphene structure 10 shown in FIG. 1 can be produced as described above. It should be noted that the graphene structure 10 shown in FIG. 2 can be formed by transferring graphene onto the substrate 11 that has been laminated with the dopant layer 122 in advance, for example.

(Effect of Graphene Structure)

As described above, by the doping of the graphene layer 121 by the dopant layer 122, the resistance of the graphene layer 121 can be reduced in the graphene structure 10 according to this embodiment. Furthermore, it is possible to prevent the time degradation of the conduction characteristic of the graphene layer 121, because the sacrificial layer 13 prevents water in an environment from donating an electron to the graphene layer 121.

The graphene structure 10 according to this embodiment can be used as a transparent conductive film of a photoelectric conversion element, a solar cell, an image pickup apparatus, a touch panel, or the like. The graphene structure 10 is favorable for these devices because it has a high conductivity and a temporally-stable conduction characteristic, as described above.

### Second Embodiment

A graphene structure according to a second embodiment of the present disclosure will be described. It should be noted that in this embodiment, descriptions on configurations that are the same as those of the first embodiment will be omitted in some cases.

(Configuration of Graphene Structure)

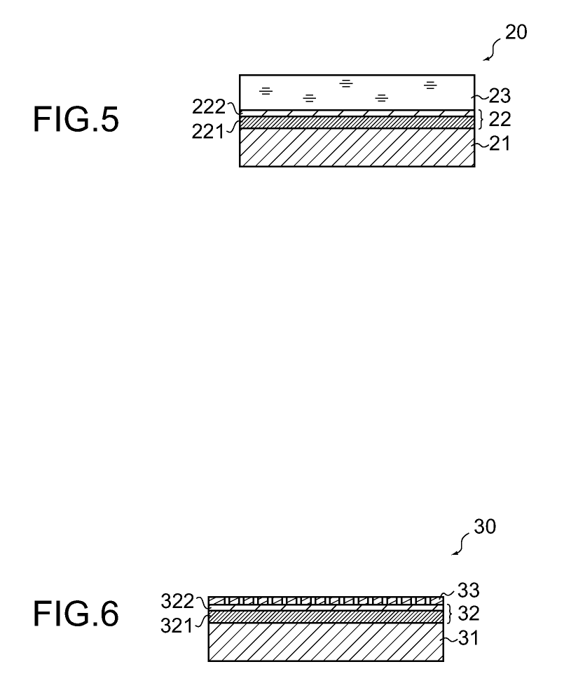

FIG. 5 is a schematic diagram showing a layer construction of a graphene structure 20 according to this embodiment. As shown in this figure, the graphene structure 20 is formed by laminating a substrate 21, a conductive layer 22, and a nonaqueous solution layer 23 in the stated order.

The substrate 21 is a supporting substrate of the graphene structure 20. The material, the size, and the like of the substrate 21 are not particularly limited, and a quartz substrate may be used as the material, for example. If the graphene structure 20 is expected to have optical transparency, the substrate 21 may be formed of a material which has optical transparency.

The conductive layer 22 is constituted of a graphene layer 221 and a dopant layer 222. With respect to the graphene layer 221 and the dopant layer 222, the graphene layer 221 may be a lower layer (on the side of the substrate 21) as shown in FIG. 5, or the dopant layer 222 may be a lower layer.

The graphene layer 221 is formed of graphene. In this embodiment also, single-layer graphene is favorable in terms of the optical transparency of the graphene structure 20 and because no delamination is caused.

The dopant layer 222 is formed of a dopant. The dopant can be selected from materials having a higher oxidation-reduction potential than water. As shown in FIG. 5, since the dopant layer 222 is in contact with the graphene layer 221, the dopant located near the interface is chemically adsorbed by the graphene of the graphene layer 221 to be doped (chemical doping).

The nonaqueous solution layer 23 is formed of a liquid that has a higher oxidation-reduction potential than water and does not contain water. The example of the liquid is a non-aqueous liquid such as a carbonate and ether that are used as an electrolyte solution for a cell or the like, or a hydrophilic liquid such as a dehydrated ionic liquid. Since there is no water in the nonaqueous solution layer 23, the above-mentioned time degradation of the conduction characteristic due to water is not caused.

The graphene structure 20 according to this embodiment is formed as described above. The graphene structure 20 can be used as, for example, an electrode of a cell that is immersed in an electrolyte solution.

(Production Method of Graphene Structure)

A production method of the graphene structure 20 will be described. The production method of the graphene structure 20 according to this embodiment may be the same as that of the first embodiment up to the step of laminating the dopant layer 222.

After laminating the dopant layer 222, the nonaqueous solution layer 23 is laminated on it. This can be achieved by immersing a laminated body, which is formed by laminating the graphene layer 221 and the dopant layer 222 on the substrate 21, in a nonaqueous solution, for example. The graphene structure 20 shown in FIG. 5 can be produced as described above.

(Effect of Graphene Structure)

As described above, by the doping of the graphene layer 221 by the dopant layer 222, the resistance of the graphene layer 221 can be reduced in the graphene structure 20 according to this embodiment. Furthermore, because there is no water in the nonaqueous solution layer 23 and water near the interface is thus prevented from donating an electron to the graphene layer 221, it is possible to prevent the time degradation of the conduction characteristic of the graphene layer 221.

The graphene structure 20 according to this embodiment can be used as a transparent conductive film of a photoelectric conversion element, a solar cell, an image pickup apparatus, a touch panel, or the like. The graphene structure 20 is favorable for these devices because it has a high conductivity and a temporally-stable conduction characteristic, as described above.

### Third Embodiment

A graphene structure according to a third embodiment of the present disclosure will be described. It should be noted that in this embodiment, descriptions on configurations that are the same as those of the first embodiment will be omitted in some cases.

(Configuration of Graphene Structure)

FIG. 6 is a schematic diagram showing a layer construction of the graphene structure 30 according to this embodiment. As shown in this figure, the graphene structure 30 is formed by laminating a substrate 31, a conductive layer 32, and a sealing layer 33 in the stated order.

The substrate 31 is a supporting substrate of the graphene structure 30. The material, the size, and the like of the substrate 31 are not particularly limited, and a quartz substrate may be used as the material, for example. If the graphene structure 30 is expected to have optical transparency, the substrate 31 may be formed of a material which has optical transparency.

The conductive layer 32 is constituted of a graphene layer 321 and a dopant layer 322. With respect to the graphene layer 321 and the dopant layer 322, the graphene layer 321 may be a lower layer (on the side of the substrate 31) as shown in FIG. 6, or the dopant layer 322 may be a lower layer.

The graphene layer 321 is formed of graphene. In this embodiment also, single-layer graphene is favorable in terms of the optical transparency of the graphene structure 30 and because no delamination is caused.

The dopant layer 322 is formed of a dopant. The dopant can be selected from materials having a higher oxidation-reduction potential than water. As shown in FIG. 6, since the dopant layer 322 is in contact with the graphene layer 321, the dopant located near the interface is chemically adsorbed by the graphene of the graphene layer 321 to be doped (chemical doping).

The sealing layer 33 is formed of a material that has a higher oxidation-reduction potential than water and shields water (in the liquid and vapor phases), and covers the entire surface of the conductive layer 32 so as not to expose it. The sealing layer 33 prevents water in an environment from reaching the conductive layer 32. That is, water is prevented from donating an electron to the graphene layer 321. The sealing layer 33 may be formed of any material as long as water can be prevented from reaching the conductive layer 32. Even if the sealing layer 33 is formed of an insulating material, by making it thin, a current flowing through the conductive layer 32 can pass (leak) through the sealing layer 33 so that an electrical contact of the conductive layer 32 can be secured.

The graphene structure 30 according to this embodiment is formed as described above. The graphene structure 30 can be used as an electrode of a touch panel, a solar cell, or the like.

(Production method of Graphene Structure)

A production method of the graphene structure 30 will be described. The production method of the graphene structure 30 according to this embodiment may be the same as that of the first embodiment up to the step of laminating the dopant layer 322.

After laminating the dopant layer 322, the sealing layer 33 is laminated on it. A solution including the material of the sealing layer 33 is applied onto the dopant layer 322 by spin-coating and dried, for example. Accordingly, the sealing layer 33 can be formed. It is desirable that the spin coating is performed in dry air to prevent water in air from attaching to the dopant layer 322 or the like. The graphene structure 30 shown in FIG. 6 can be produced as described above.

(Effect of Graphene Structure)

As described above, by the doping of the graphene layer 321 by the dopant layer 322, the resistance of the graphene layer 321 can be reduced in the graphene structure 30 according to this embodiment. Furthermore, because the sealing layer 33 prevents water in an environment from reaching the conductive layer 32 and water in an environment can thus be prevented from donating an electron to the graphene layer 321, it is possible to prevent the time degradation of the conduction characteristic of the graphene layer 321.

The graphene structure 30 according to this embodiment can be used as a transparent conductive film of a photoelectric conversion element, a solar cell, an image pickup apparatus, a touch panel, or the like. The graphene structure 30 is favorable for these devices because it has a high conductivity and a temporally-stable conduction characteristic, as described above.

### Fourth Embodiment

A graphene structure according to a fourth embodiment of the present disclosure will be described. It should be noted that in this embodiment, descriptions on configurations that are the same as those of the first embodiment will be omitted in some cases.

(Configuration of Graphene Structure)

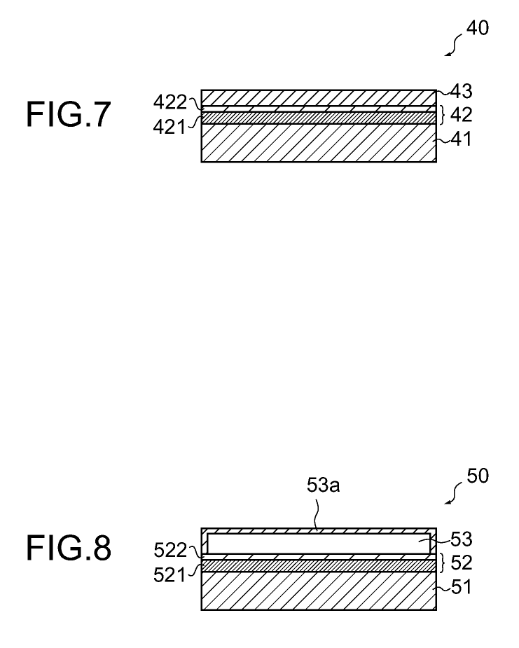

FIG. 7 is a schematic diagram showing a layer construction of a graphene structure 40 according to this embodiment. As shown in this figure, the graphene structure 40 is formed by laminating a substrate 41, a conductive layer 42, and a surplus dopant layer 44 in the stated order.

The substrate 41 is a supporting substrate of the graphene structure 40. The material, the size, and the like of the substrate 41 are not particularly limited, and a quartz substrate may be used as the material, for example. If the graphene structure 40 is expected to have optical transparency, the substrate 41 may be formed of a material which has optical transparency.

The conductive layer 42 is constituted of a graphene layer 421 and a dopant layer 422. With respect to the graphene layer 421 and the dopant layer 422, the graphene layer 421 may be a lower layer (on the side of the substrate 41) as shown in FIG. 7, or the dopant layer 422 may be a lower layer.

The graphene layer 421 is formed of graphene. In this embodiment also, single-layer graphene is favorable in terms of the optical transparency of the graphene structure 40 and because no delamination is caused.

The dopant layer 422 is formed of a dopant. The dopant can be selected from materials having a higher oxidation-reduction potential than water. As shown in FIG. 7, since the dopant layer 422 is in contact with the graphene layer 421, the dopant located near the interface is chemically adsorbed by the graphene of the graphene layer 421 to be doped (chemical doping).

The surplus dopant layer 43 is formed of a surplus dopant with respect to the number of carbon atoms configuring graphene and which does not contribute to the doping. When an excessive amount of the dopant with respect to the number of carbon atoms configuring graphene is laminated on the graphene layer 421, the surplus dopant does not contribute to the doping. That is, in this embodiment, an excessive amount of the dopant is laminated on the graphene layer 421 intentionally so that the dopant layer 422 which contributes to the doping of graphene and the surplus dopant layer 43 which does not contribute to the doping of graphene are formed.

The surplus dopant layer 43 prevents water in an environment from donating an electron to the conductive layer 42. Accordingly, it is possible to prevent the time degradation of the conduction characteristic of the conductive layer 42.

The graphene structure 40 according to this embodiment is formed as described above. The graphene structure 40 can be used as an electrode of a touch panel, a solar cell, or the like.

(Production Method of Graphene Structure)

A production method of the graphene structure 40 will be described. The production method of the graphene structure 40 according to this embodiment may be the same as that of the first embodiment up to the step of laminating the graphene layer 421.

After laminating the graphene layer 421, the dopant layer 422 is laminated on the graphene layer 421 so that graphene is doped with the dopant. This can be achieved by the method as follows. That is, gold chloride is dried in a vacuum at room temperature for 4 hours. By dissolving it into a solvent (e.g., dehydrated nitromethane), a 10 mM solution (hereinafter referred to as dopant solution) is obtained. The dopant solution is applied onto the graphene layer 421 by spin-coating (2000 rpm, 40 seconds) and dried in a vacuum. Accordingly, the dopant layer 422 is formed.

At this time, it is possible to form the surplus dopant layer 43 as well as the dopant layer 422 by increasing the concentration of the dopant solution. Alternatively, the surplus dopant layer 43 may be formed by applying the dopant solution by spin-coating and drying it again after forming the dopant layer 422. The graphene structure 40 shown in FIG. 7 can be formed as described above.

(Effect of Graphene Structure)

As described above, by the doping of the graphene layer 421 by the dopant layer 422, the resistance of the graphene layer 421 can be reduced in the graphene structure 40 according to this embodiment. Furthermore, because the surplus dopant layer 43 accepts an electron from water in an environment and this prevents the water in an environment from donating an electron to the graphene layer 421, it is possible to prevent the time degradation of the conduction characteristic of the graphene layer 421.

The graphene structure 40 according to this embodiment can be used as a transparent conductive film of a photoelectric conversion element, a solar cell, an image pickup apparatus, a touch panel, or the like. The graphene structure 40 is favorable for these devices because it has a high conductivity and a temporally-stable conduction characteristic, as described above.

### Fifth Embodiment

A graphene structure according to a fifth embodiment of the present disclosure will be described. It should be noted that in this embodiment, descriptions on configurations that are the same as those of the first embodiment will be omitted in some cases.

(Configuration of Graphene Structure)

FIG. 8 is a schematic diagram showing a layer construction of the graphene structure according to this embodiment. As shown in this figure, the graphene structure 50 is formed by laminating a substrate 51, a conductive layer 52, and a dried gas layer 53 in the stated order.

The substrate 51 is a supporting substrate of the graphene structure 50. The material, the size, and the like of the substrate 51 are not particularly limited, and a quartz substrate may be used as the material, for example. If the graphene structure 50 is expected to have optical transparency, the substrate 51 may be formed of a material which has optical transparency.

The conductive layer 52 is constituted of a graphene layer 521 and a dopant layer 522. With respect to the graphene layer 521 and the dopant layer 522, the graphene layer 521 may be a lower layer (on the side of the substrate 51) as shown in FIG. 8, or the dopant layer 522 may be a lower layer.

The graphene layer 521 is formed of graphene. In this embodiment also, single-layer graphene is favorable in terms of the optical transparency of the graphene structure 50 and because no delamination is caused.

The dopant layer 522 is formed of a dopant. The dopant can be selected from materials having a higher oxidation-reduction potential than water. As shown in FIG. 8, since the dopant layer 522 is in contact with the graphene layer 521, the dopant located near the interface is chemically adsorbed by the graphene of the graphene layer 521 to be doped (chemical doping).

The dried gas layer 53 is formed of gas which does not contain water. The dried gas layer 53 may be enclosed in a room formed by a cell 53a as shown in FIG. 9. The gas may be, for example, a dried gas obtained by removing water in gas by coating an inner wall of the cell 53a with a material which absorbs water. The type of gas is not particularly limited. A dry air or an inert gas may be used as the gas. Since there is no water in the dried gas layer 53, the above-mentioned time degradation of the conduction characteristic due to water is not caused.

The graphene structure 50 according to this embodiment is formed as described above. The graphene structure 50 can be used as an electrode of a touch panel, a solar cell, or the like.

(Production Method of Graphene Structure)

A production method of the graphene structure 50 will be described. The production method of the graphene structure 50 according to this embodiment may be the same as that of the first embodiment up to the step of laminating the dopant layer 522.

After laminating the dopant layer 522, the cell 53a is mounted on it. A dried gas is introduced into the cell 53a or a water absorber provided within the cell 53a removes water in gas. Accordingly, the dried gas layer 53 can be formed.

(Effect of Graphene Structure)

As described above, by the doping of the graphene layer 521 by the dopant layer 522, the resistance of the graphene layer 521 can be reduced in the graphene structure 50 according to this embodiment. Furthermore, because the dried gas layer 53 prevents water in an environment from reaching the conductive layer 52 and this prevents the water in an environment from donating an electron to the graphene layer 521, it is possible to prevent the time degradation of the conduction characteristic of the graphene layer 521.

The graphene structure 50 according to this embodiment can be used as a transparent conductive film of a photoelectric conversion element, a solar cell, an image pickup apparatus, a touch panel, or the like. The graphene structure 50 is favorable for these devices because it has a high conductivity and a temporally-stable conduction characteristic, as described above.

It should be noted that the present disclosure may also employ the following configurations.

(1) A graphene structure, including:

a conductive layer formed of graphene doped with a dopant; and

a protective layer that is laminated on the conductive layer and formed of a material having a higher oxidation-reduction potential than water.

(2) The graphene structure according to Item (1), in which

the protective layer is a sacrificial layer formed of a material that reacts with water.

(3) The graphene structure according to Item (1) or (2), in which

the protective layer is a nonaqueous solution layer formed of a nonaqueous solution.

(4) The graphene structure according to any one of Items (1) to (3), in which

the protective layer is a sealing layer that is formed of a material that shields water and covers the conductive layer.

(5) The graphene structure according to any one of Items (1) to (4), in which

the protective layer is a surplus dopant layer formed of a surplus amount of the dopant which does not contribute to the doping.

(6) The graphene structure according to any one of Items (1) to (5), in which

the protective layer is a dried gas layer formed of a dried gas which does not contain water.

(7) A method of producing a graphene structure, including:

forming a conductive layer by doping graphene with a dopant; and

laminating a protective layer formed of a material having a higher oxidation-reduction potential than water on the conductive layer.

(8) A photoelectric conversion element that uses a graphene structure as a transparent conductive film, the graphene structure including a conductive layer formed of graphene doped with a dopant and a protective layer that is laminated on the conductive layer and formed of a material having a higher oxidation-reduction potential than water.

(9) A solar cell that uses a graphene structure as a transparent conductive film, the graphene structure including a conductive layer formed of graphene doped with a dopant and a protective layer that is laminated on the conductive layer and formed of a material having a higher oxidation-reduction potential than water.

(10) An image pickup apparatus that uses a graphene structure as a transparent conductive film, the graphene structure including a conductive layer formed of graphene doped with a dopant and a protective layer that is laminated on the conductive layer and formed of a material having a higher oxidation-reduction potential than water.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A graphene structure, comprising:
a conductive layer formed of graphene doped with a dopant; and
a protective layer that is laminated on the conductive layer and formed of a material having a higher oxidation-reduction potential than water.

2. The graphene structure according to claim 1, wherein
the protective layer is a sacrificial layer formed of a material that reacts with water.

3. The graphene structure according to claim 1, wherein
the protective layer is a nonaqueous solution layer formed of a nonaqueous solution.

4. The graphene structure according to claim 1, wherein
the protective layer is a sealing layer that is formed of a material that shields water and covers the conductive layer.

5. The graphene structure according to claim 1, wherein
the protective layer is a surplus dopant layer formed of a surplus amount of the dopant which does not contribute to the doping.

6. The graphene structure according to claim 1, wherein
the protective layer is a dried gas layer formed of a dried gas which does not contain water.

7. A method of producing a graphene structure, comprising:
forming a conductive layer by doping graphene with a dopant; and
laminating a protective layer formed of a material having a higher oxidation-reduction potential than water on the conductive layer.

8. A photoelectric conversion element that uses a graphene structure as a transparent conductive film, the graphene structure including a conductive layer formed of graphene doped with a dopant and a protective layer that is laminated on the conductive layer and formed of a material having a higher oxidation-reduction potential than water.

9. A solar cell that uses a graphene structure as a transparent conductive film, the graphene structure including a conductive layer formed of graphene doped with a dopant and a protective layer that is laminated on the conductive layer and formed of a material having a higher oxidation-reduction potential than water.

10. An image pickup apparatus that uses a graphene structure as a transparent conductive film, the graphene structure including a conductive layer formed of graphene doped with a dopant and a protective layer that is laminated on the conductive layer and formed of a material having a higher oxidation-reduction potential than water.
